(19) United States
(12) Patent Application Publication
(10) Pub. No.: US 2026/0130168 A1
(43) Pub. Date: May 7, 2026

(54) WAFER BOAT DEVICE AND PLASMA DISSOCIATION FURNACE TUBE SYSTEM

(71) Applicant: METAL INDUSTRIES RESEARCH & DEVELOPMENT CENTRE, KAOHSIUNG (TW)

(72) Inventors: Zheng Xi LI, Tainan City (TW); Ping-Tun HUANG, Changhua County (TW); Cheng-Yuan HUNG, Kaohsiung City (TW); Chang-Sin YE, Tainan City (TW)

(21) Appl. No.: 18/938,285

(22) Filed: Nov. 6, 2024

(51) Int. Cl. H01L 21/673; C23C 16/458; C23C 16/505; H01J 37/32

(52) U.S. Cl. CPC H10P 72/13; C23C 16/4587; C23C 16/505; H01J 37/3244; H01J 37/32715; H01J 37/32082; H01J 2237/2007

(57) ABSTRACT

A wafer boat device includes first positive and negative electrode plates that are opposite to each other, and a plasma region, a coating region, and a feed region located between the first positive and negative electrode plates. The plasma region includes plural second positive and negative electrode plates. A first circuit breaking region separates the coating region from the plasma region. The coating region includes plural third positive and negative electrode plates. A second circuit breaking region separates the feed region from the coating region. The feed region includes plural fourth positive and fourth electrode plates, and the feed region is electrically connected to the plasma region. The second positive and negative electrode plates, the third positive and negative electrode plates, and the fourth positive and negative electrode plates are arranged at intervals from each other in a staggered manner with the first positive and negative electrode plates.

### BACKGROUND

### Field of Invention

The present disclosure relates to a deposition technology, and more particularly, to a wafer boat device and a plasma dissociation furnace tube system.

### Description of Related Art

Among conventional semiconductor process technologies, tunnel oxide passivated contact (TOPCon) technology is regarded as the most important research direction in the solar energy industry in the future. The well-known German solar research institution, Institute for Solar Energy Research Hamelin (ISFH), conducted simulation calculations on solar cells with different structures based on the concept of carrier selectivity, and found that the efficiency of bilaterally passivated TOPCon solar cells can reach 28.2% to 28.7%. In addition, the European Solar Test Installation (ESTI) Institute recently certified that the efficiency of the perovskite-silicon tandem solar cells provided by Longi Green Energy Technology Co., Ltd. has exceeded 30%.

In order to increase the production output of solar cells, the solar power plants use plasma dissociation furnace tube systems to produce the solar cells. In a current wafer boat design of the plasma dissociation furnace tube system, wafers are placed on electrode sheets of the wafer boat. Current is introduced into the entire wafer boat through a feed end of the wafer boat to generate plasma. Thus, the introduced current also flows through the wafers. When plasma is generated, high bombardment energy is generated to bombard surfaces of the wafers.

The thin films on the surfaces of the wafers are damaged by the high bombardment energy and the plasma bombardment temperature, such that the yield of the stacking process of the solar cells is poor, especially the stacking process performed on the perovskite layer that cannot withstand the high temperature.

### SUMMARY

Therefore, one objective of the present disclosure is to provide a wafer boat device and a plasma dissociation furnace tube system, which can significantly reduce plasma bombardment on wafers and reduce thin film loss of surfaces of the wafers, thereby increasing the deposition coverage and the density of thin films during stacking operations of solar cells and reducing thin film defects.

According to the aforementioned objectives, the present disclosure provides a wafer boat device. The wafer boat device includes a first positive electrode plate, a first negative electrode plates, a plasma region, a coating region, and a feed region. The first negative electrode plate is opposite to the first positive electrode plate. The plasma region is disposed between the first positive electrode plate and the first negative electrode plate. The plasma region includes plural second positive electrode plates and plural second negative electrode plates. The coating region is disposed between the first positive electrode plate and the first negative electrode plate, and is separated from the plasma region by a first circuit breaking region. The coating region includes plural third positive electrode plates and plural of third negative electrode plates, and each of the third positive electrode plates and the third negative electrode plates is configured to carry plural cells. The feed region is disposed between the first positive electrode plate and the first negative electrode plate, and is separated from the coating region by a second circuit breaking region. The feed region includes plural fourth positive electrode plates and plural fourth negative electrode plates, and the feed region is electrically connected to the plasma region. All the second positive electrode plates and the second negative electrode plates, the third positive electrode plates and the third negative electrode plates, and the fourth positive electrode plates and the fourth negative electrode plates are arranged at intervals from each other in a staggered manner with the first positive electrode plate and the first negative electrode plate. The wafer boat device further includes another first positive electrode plate disposed adjacent to the first negative electrode plate, such that the first negative electrode plate is between the another first positive electrode plate and the first positive electrode plate. Or, the wafer boat device further includes another first negative electrode plate disposed adjacent to the first positive electrode plate, such that the first positive electrode plate being between the another first negative electrode plate and the first negative electrode plate.

According to one embodiment of the present disclosure, the first circuit breaking region electrically isolates the coating region from the plasma region, and the second circuit breaking region electrically isolates the feed region from the coating region, in which a length of each of the first circuit breaking region and the second circuit breaking region may be ranging from about 50 mm to about 80 mm.

According to one embodiment of the present disclosure, a length of the wafer boat device is ranging from about 1600 mm to about 2300 mm, a length of the plasma region is ranging from about 200 mm to about 350 mm, a length of the coating region is ranging from about 300 mm to about 500 mm, and a length of the feed region is ranging from about 50 mm to about 100 mm.

According to one embodiment of the present disclosure, an electrical conductivity of the first positive electrode plate and an electrical conductivity of the first negative electrode plate are both greater than electrical conductivities of the second positive electrode plates, the second negative electrode plates, the third positive electrode plates, the third positive electrode plates, the fourth positive electrode plates, and the fourth negative electrode plates.

According to one embodiment of the present disclosure, a ratio of the electrical conductivity of the first positive electrode plate to each of the electrical conductivities of the second positive electrode plates, the third positive electrode plates, and the fourth positive electrode plates is ranging from 2.5:1 to 175:1, and a ratio of the electrical conductivity of the first negative electrode plate to each of the electrical conductivities of the second negative electrode plates, the third negative electrode plates, and the fourth negative electrode plates is ranging from 2.5:1 to 175:1.

According to one embodiment of the present disclosure, each of the first positive electrode plate and the first negative electrode plate includes a main body; and a metal layer. The metal layer covers at least one side surface of the main body. An electrical conductivity of the metal layer is greater than an electrical conductivity of the main body.

According to one embodiment of the present disclosure, a material of the metal layer includes copper paste or silver paste, and a material of the main body may include graphite.

According to one embodiment of the present disclosure, materials of the second positive electrode plates, the second negative electrode plates, the third positive electrode plates, the third negative electrode plates, the fourth positive electrode plates, and the fourth negative electrode plates include graphite.

According to one embodiment of the present disclosure, a gap between the first positive electrode plate, the first negative electrode plate, the second positive electrode plate, and the second negative electrode plate, a gap between the first positive electrode plate, the first negative electrode plate, the third positive electrode plate, and the third negative electrode plate, and a gap between the first positive electrode plate, the first negative electrode plate, the fourth positive electrode plate, and the fourth negative electrode plate are all ranging from about 10 mm to 20 mm.

According to the aforementioned objectives, the present disclosure further provides a plasma dissociation furnace tube system. The plasma dissociation furnace tube system includes a furnace tube, the aforementioned wafer boat device, a gas extraction device, a power module, a process gas supply system, and a precursor gas supply system. The furnace tube has a reaction chamber. The wafer boat device is disposed in the reaction chamber. The gas extraction device is fluidly connected to the reaction chamber. The gas extraction device is configured to perform a gas extraction operation on the reaction chamber from the feed region to drive a plasma generated in the plasma region to flow to the coating region. The power module is electrically connected to the first positive electrode plate, the second positive electrode plates, the fourth positive electrode plates, the first negative electrode plate, the second negative electrode plates, and the four negative electrode plates. The power module is configured to supply a power to the first positive electrode plate, the first negative electrode plate, the feed region, and the plasma region. The process gas supply system is fluidly connected to the reaction chamber and is configured to supply at least one process gas to the reaction chamber. The precursor gas supply system is fluidly connected to the reaction chamber and is configured to supply at least one precursor gas to the reaction chamber.

According to one embodiment of the present disclosure, the furnace tube is a quartz furnace tube.

According to one embodiment of the present disclosure, the power module is a radio frequency power module, and a working frequency of the power module is 40 kHz.

According to one embodiment of the present disclosure, the process gas supply system is adjacent to the plasma region, and the process gas supply system is configured to supply the at least one process gas toward the plasma region.

According to one embodiment of the present disclosure, the precursor gas supply system is configured to supply the at least one precursor gas from a bottom of the wafer boat device.

According to the aforementioned description, the coating region is separated from the plasma region and the feed region by the first circuit breaking region and the second circuit breaking region respectively, such that the current entering the wafer boat device from the feed region does not flow through the electrode plates in the coating region. As a result, the plasma with high bombardment energy will not be generated between the wafers in the coating region. Therefore, the plasma bombardment on the films on the wafers carried by the coating region can be reduced, and the coverage and the density of the films are increased, thereby enhancing the quality of the films and the photoelectric conversion efficiency of the solar cells to achieve large-area batch plasma-enhanced deposition.

In addition, the reaction chamber is evacuated from the feed region by the gas extraction device to form a gas flow in the reaction chamber to drive the plasma generated in the plasma region to flow to the coating region to perform a plasma-enhanced coating operation. The plasma dissociates in the plasma region next to the coating region, such that compared with the traditional remote plasma system, the present disclosure can ensure the stability of the plasma dissociation gas which flows to the coating region, thereby enhancing the coating efficiency and the film quality. Furthermore, with the method of dissociating the plasma in the plasma region and then driving the plasma to the adjacent coating region, even if the wafer warps due to the gas flow and temperature, short circuit will not be caused by plasma bombardment because no current flows through the wafer.

### BRIEF DESCRIPTION OF THE DRAWINGS

Aspects of the present disclosure are best understood from the following detailed description in conjunction with the accompanying figures. It is noted that in accordance with the standard practice in the industry, various features are not drawn to scale. In fact, dimensions of the various features can be arbitrarily increased or reduced for clarity of discussion.

FIG. 1 is a schematic three-dimensional view of a wafer boat device in accordance with an embodiment of the present disclosure.

FIG. 2 is a schematic front view of a wafer boat device in accordance with an embodiment of the present disclosure.

FIG. 3 is a partial cross-sectional view of a first positive electrode plate in accordance with an embodiment of the present disclosure.

FIG. 4 is a schematic diagram of a plasma dissociation furnace tube system in accordance with an embodiment of the present disclosure.

### DETAILED DESCRIPTION

The embodiments of the present disclosure are discussed in detail below. However, it will be appreciated that the embodiments provide many applicable concepts that can be implemented in various specific contents. The embodiments discussed and disclosed are for illustrative purposes only and are not intended to limit the scope of the present disclosure. All of the embodiments of the present disclosure disclose various different features, and these features may be implemented separately or in combination as desired.

In addition, the terms "first", "second", and the like, as used herein, are not intended to mean a sequence or order, and are merely used to distinguish elements or operations described in the same technical terms.

The spatial relationship between two elements described in the present disclosure applies not only to the orientation depicted in the drawings, but also to the orientations not represented by the drawings, such as the orientation of the inversion. Moreover, the terms "connected", "electrically connected", or the like between two components referred to in the present disclosure are not limited to the direct connection or electrical connection of the two components, and may also include indirect connection or electrical connection as required.

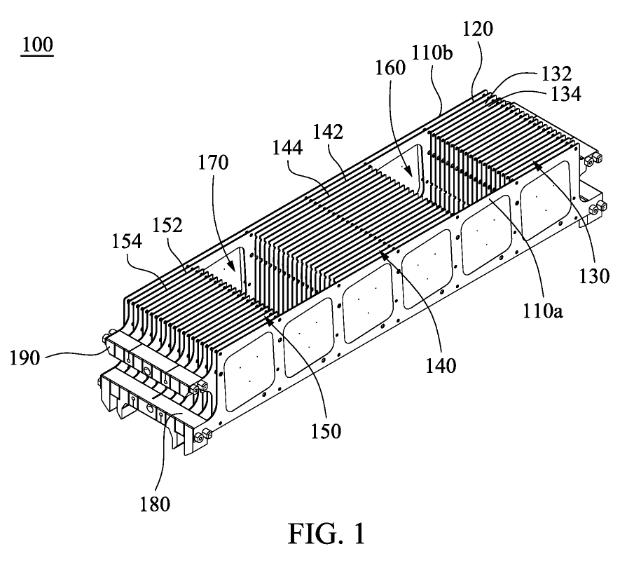

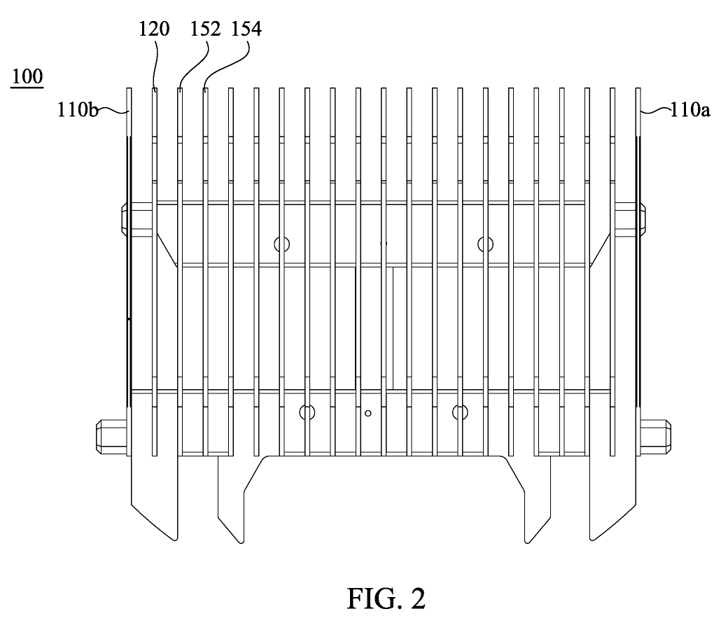

Referring to FIG. 1 and FIG. 2, FIG. 1 and FIG. 2 respectively illustrate a schematic three-dimensional view and a schematic front view of a wafer boat device 100 in accordance with an embodiment of the present disclosure. The wafer boat device 100 may be applied in a furnace tube plasma-enhanced deposition process, such as a furnace tube plasma-enhanced atomic layer deposition process, to perform large-area batch thin film deposition. The wafer boat device 100 may mainly include a first positive electrode plate 110a, a first negative electrode plate 120, a plasma region 130, a coating region 140, a feed region 150, a first circuit breaking region 160, and a second circuit breaking region 170.

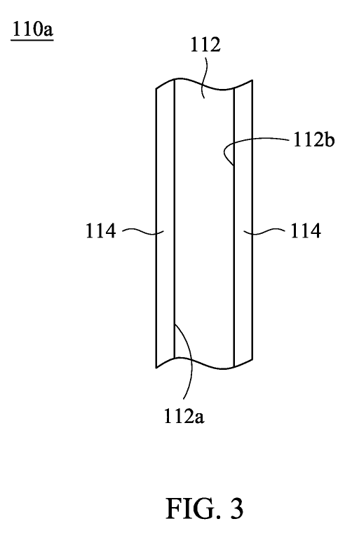

The first positive electrode plate 110a and the first negative electrode plate 120 are opposite to each other and spaced apart from each other. The first positive electrode plate 110a may be substantially parallel to the first negative electrode plate 120. The first positive electrode plate 110a may have a high electrical conductivity. Referring to FIG. 3 first, FIG. 3 is a partial cross-sectional view of a first positive electrode plate 110a in accordance with an embodiment of the present disclosure. In the example shown in FIG. 3, the first positive electrode plate 110a is a multi-layer composite structure and includes a main body 112 and a metal layer 114. The main body 112 is a plate structure, and has two side surfaces 112a and 112b that are opposite to each other. The metal layer 114 covers at least one of the side surfaces 112a and 112b of the main body 112. In the example shown in FIG. 3, the metal layer 114 covers the two side surfaces 112a and 112b of the main body 112. An electrical conductivity of the metal layer 114 is greater than an electrical conductivity of the main body 112. For example, a material of the main body 112 may include graphite. The metal layer 114 is a high temperature resistant and good conductor metal. A melting point of the metal layer 114 may be, for example, equal to or greater than 400°C. For example, a material of the metal layer 114 may include copper paste or silver paste. An electrical conductivity of copper is about 5.8×10⁷ S/m, and an electrical conductivity of silver is about 7×10⁷ S/m.

The structure of the first positive electrode plate 110a is not limited to the above example. In other examples, the first positive electrode plate 110a is a single-layer plate structure. The first positive electrode plate 110a is a high temperature resistant and good conductor metal plate, such as a copper plate or a silver plate.

The first negative electrode plate 120 may also have a high electrical conductivity. The electrical conductivities of the first negative electrode plate 120 and the first positive electrode plate 110a may be the same or may be different from each other. The first negative electrode plate 120 may be a multi-layer composite plate structure or a single-layer plate structure. In the example where the first negative electrode plate 120 is a multi-layer composite plate structure, the first negative electrode plate 120 may be as the first positive electrode plate 110a and include a main body and a metal layer covering at least one side surface of the main body. The properties and the materials of the main body and the metal layer of the first negative electrode plate 120 may be the same as those of the first positive electrode plate 110a, and will not be repeated here.

Referring to FIG. 1 again, the plasma region 130 is disposed between the first positive electrode plate 110a and the first negative electrode plate 120. The plasma region 130 can dissociate process gases to form plasma. The plasma region 130 may include plural second positive electrode plates 132 and plural second negative electrode plates 134. The second positive electrode plates 132 and the second negative electrode plates 134 may be substantially parallel to the first positive electrode plate 110a and the first negative electrode plate 120. The second positive electrode plates 132 and the second negative electrode plates 134 are sandwiched between the first positive electrode plate 110a and the first negative electrode plate 120. The first positive electrode plate 110a, the first negative electrode plate 120, the second positive electrode plates 132, and the second negative electrode plates 134 are arranged in a staggered manner and are spaced apart from each other. For example, a gap between any adjacent two of the first positive electrode plate 110a, the first negative electrode plate 120, the second positive electrode plates 132, and the second negative electrode plates 134 may be ranging from about 10 mm to about 20 mm.

Electrical conductivities of the second positive electrode plates 132 and the second negative electrode plates 134 may be the same or may be different from each other. In some examples, the electrical conductivities of the first positive electrode plate 110a and the first negative electrode plate 120 are both greater than the electrical conductivities of the second positive electrode plates 132 and the second negative electrode plates 134. For example, a ratio of the electrical conductivity of the first positive electrode plate 110a to the electrical conductivity of the second positive electrode plates 132 may be ranging from 2.5:1 to 175:1, and a ratio of the electrical conductivity of the first negative electrode plate 120 to the electrical conductivity of the second negative electrode plates 134 may be ranging from 2.5:1 to 175:1. Materials of the second positive electrode plates 132 and the second negative electrode plates 134 may include graphite, for example.

The coating region 140 is disposed between the first positive electrode plate 110a and the first negative electrode plate 120. The coating region 140 and the plasma region 130 are separated by a first circuit breaking region 160. The arrangement of the first circuit breaking region 160 electrically isolates the coating region 140 from the plasma region 130. The coating region 140 includes plural third positive electrode plates 142 and plural third negative electrode plates 144. The third positive electrode plates 142 and the third negative electrode plate 144 may be substantially parallel to the first positive electrode plate 110a and the first negative electrode plate 120, and are sandwiched between the first positive electrode plate 110a and the first negative electrode plate 120. The first positive electrode plate 110a, the first negative electrode plate 120, the third positive electrode plates 142, and the third negative electrode plates 144 are arranged at intervals from each other in a staggered manner. For example, a gap between any adjacent two of the first positive electrode plate 110a, the first negative electrode plate 120, the third positive electrode plates 142, and the third negative electrode plates 144 may be ranging about 10 mm to about 20 mm.

Each of the third positive electrode plates 142 and the third negative electrode plates 144 can carry plural wafers. Specifically, each of the third positive electrode plates 142 and the third negative electrode plates 144 has two side surfaces that are opposite to each other, and the wafers can be disposed on the two side surfaces. The arrangement of the wafers is well known to a person having ordinary skill in the art and will not be described herein. The number of the third positive electrode plates 142 and the third negative electrode plates 144 may be the same as or different from the number of the second positive electrode plates 132 and the second negative electrode plates 134. For example, the number of the third positive electrode plates 142 and the third negative electrode plates 144 may be greater than the number of the second positive electrode plates 132 and the second negative electrode plates 134. Thus, the coating region 140 can carry more wafers.

Electrical conductivities of the third positive electrode plates 142 and the third negative electrode plates 144 may be the same or may be different from each other. In some examples, the electrical conductivities of the first positive electrode plate 110a and the first negative electrode plate 120 are both greater than the electrical conductivities of the third positive electrode plates 142 and the third negative electrode plates 144. For example, a ratio of the electrical conductivity of the first positive electrode plate 110a to the electrical conductivity of the third positive electrode plate 142 may be ranging from 2.5:1 to 175:1, and a ratio of the electrical conductivity of the first negative electrode plate 120 to the electrical conductivity of the third negative electrode plate 144 may be ranging from 2.5:1 to 175:1. Materials of the third positive electrode plates 142 and the third negative electrode plates 144 may include graphite, for example.

Similarly, the feed region 150 is disposed between the first positive electrode plate 110a and the first negative electrode plate 120. The feed region 150 and the coating region 140 are separated by a second circuit breaking region 170. That is, the plasma region 130, the first circuit breaking region 160, the coating region 140, the second circuit breaking region 170, and the feed region 150 are sequentially arranged between the first positive electrode plate 110a and the first negative electrode plate 120. The second circuit breaking region 170 can electrically isolate the feed region 150 from the coating region 140. The feed region 150 is electrically connected to the plasma region 130, such that the current introduced from the feed region 150 can be transmitted to the plasma region 130.

The feed region 150 includes plural fourth positive electrode plates 152 and plural fourth negative electrode plates 154. The fourth positive electrode plates 152 and the fourth negative electrode plates 154 may be substantially parallel to the first positive electrode plate 110a and the first negative electrode plate 120, and are sandwiched between the first positive electrode plate 110a and the first negative electrode plate 120. The first positive electrode plate 110a, the first negative electrode plate 120, the fourth positive electrode plates 152, and the fourth negative electrode plates 154 are arranged at intervals from each other in a staggered manner. For example, a gap between any adjacent two of the first positive electrode plate 110a, the first negative electrode plate 120, the fourth positive electrode plates 152, and the fourth negative electrode plates 154 may be ranging about 10 mm to about 20 mm.

The number of the fourth positive electrode plates 152 and the fourth negative electrode plates 154 is the same as the number of the second positive electrode plates 132 and the second negative electrode plates 134 of the plasma region 130. In addition, the number of the fourth positive electrode plates 152 and the fourth negative electrode plates 154 may be the same as or may be different from the number of the third positive electrode plates 142 and the third negative electrode plates 144 of the coating region 140.

Electrical conductivities of the fourth positive electrode plates 152 and the fourth negative electrode plates 154 may be the same or may be different from each other. In some examples, the electrical conductivities of the first positive electrode plate 110a and the first negative electrode plate 120 are both greater than the electrical conductivities of the fourth positive electrode plates 152 and the fourth negative electrode plates 154. For example, a ratio of the electrical conductivity of the first positive electrode plate 110a to the electrical conductivity of the fourth positive electrode plates 152 may be ranging from 2.5:1 to 175:1, and a ratio of the electrical conductivity of the first negative electrode plate 120 to the electrical conductivity of the fourth negative electrode plates 154 may be ranging from 2.5:1 to 175:1. Materials of the fourth positive electrode plates 152 and the fourth negative electrode plates 154 may include graphite, for example.

In some examples, lengths of the first circuit breaking region 160 and the second circuit breaking region 170 are both ranging from about 50 mm to about 80 mm. It can be understood that the lengths are measured along an extending direction of the first positive electrode plate 110a and the first negative electrode plate 120. When the lengths of the first circuit breaking region 160 and the second circuit breaking region 170 are smaller than 50 mm, the electric fields in the plasma region 130 and the feed region 150 may affect the coating region 140, such that the quality of the coating films in the coating region 140 is affected. When the lengths of the first circuit breaking region 160 and the second circuit breaking region 170 is greater than 80 mm, under the condition that a length of the wafer boat device 100 is fixed, a length of the coating region 140 will be reduced, resulting in a decrease in production capacity.

In some exemplary examples, the length of the wafer boat device 100 is ranging from about 1600 mm to about 2300 mm, a length of the plasma region 130 is ranging from about 200 mm to about 350 mm, a length of the coating region 140 is ranging from about 300 mm to about 500 mm, and a length of the feed region 150 is ranging from about 50 mm to about 100 mm.

A current and electric field analysis is conducted on the wafer boat device 100. After the current enters the wafer boat device 100 from the feed region 150 and the first positive electrode plate 110a and the first negative electrode plate 120 on both sides of the feed region 150, the current is concentrated in the feed region 150 and the plasma region 130. This means that the designs of the first circuit breaking region 160 and the second circuit breaking region 170 can indeed perform the circuit breaking functions. In addition, the electric field is concentrated between the fourth positive electrode plates 152 and the fourth negative electrode plates 154 in the feed region 150 and between the second positive electrode plates 132 and the second negative electrode plates 134 in the plasma region 130, and there is only a very small amount of electric field between the third positive electrode plates 142 and the third negative electrode plates 144 in the middle coating region 140. It can be seen from the analysis results that the first circuit breaking region 160 and the second circuit breaking region 170 are used to enlarge the distances between the coating region 140 and the plasma region 130 and the feed region 150 on both sides of the coating region 140 respectively to generate coupling. When coupling occurred in the coating region 140, plasma will not be generated between the third positive electrode plates 142 and the third negative electrode plates 144.

The arrangement of the first circuit breaking region 160 and the second circuit breaking region 170 can separate the coating region 140 from the plasma region 130 and the feed region 150 respectively, such that current can be blocked from flowing through the third positive electrode plates 142 and the third negative electrode plates 144 of the coating region 140. Therefore, no plasma is generated between the third positive electrode plates 142 and the third negative electrode plates 144 of the coating region 140. Accordingly, plasma bombardment on the films on the wafers carried by the coating region 140 can be reduced, and the quality of the films can be enhanced, thereby achieving large-area batch plasma-enhanced deposition.

In some examples, as shown in FIG. 1, the wafer boat device 100 further includes another first positive electrode plate 110b. A structure and a material of the first positive electrode plate 110b may be the same as those of the first positive electrode plate 110a. The first positive electrode plate 110b is adjacent to the first negative electrode plate 120 with a gap and located outside the first negative electrode plate 120, such that the first negative electrode plate 120 is between the first positive electrode plate 110b and the first positive electrode plate 110a. The design of the wafer boat device 100 including two first positive electrode plates 110a and 110b can enhance the electrical transmission efficiency and the stability of the wafer boat device 100. In the examples, the first positive electrode plate 110b, the first positive electrode plate 110a, the second positive electrode plates 132, and the fourth positive electrode plates 152 may be electrically connected through, for example, a connection unit 180, and the first negative electrode plate 120, the second negative electrode plates 134, and the fourth negative electrode plates 154 may be electrically connected through, for example, a connection unit 190.

It can be understood that in other examples, based on the configuration of the system, the aforementioned electrode plates can also have different electrical properties, i.e. the aforementioned positive electrode plates can be used as the negative electrode plates of the wafer boat device, and the negative electrode plates can be used as the positive plates of the wafer boat device. Therefore, similar to the configuration of the electrode plates shown in FIG. 1, the two outermost electrode plates of the wafer boat device are negative electrode plates, and the other electrode plates are sequentially arranged between the two outermost electrode plates in a staggered manner of positive and negative electrodes.

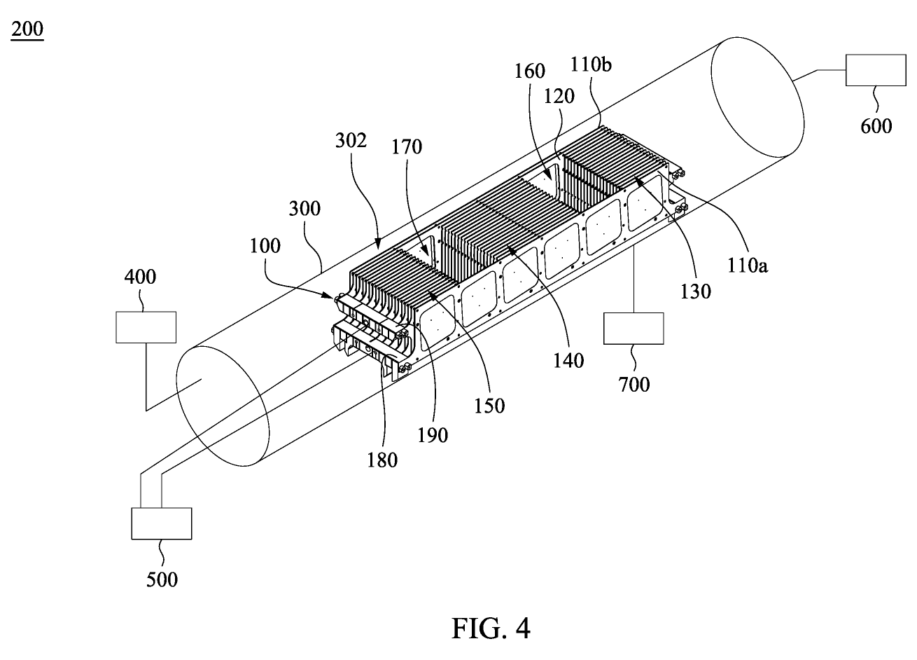

The wafer boat device 100 may be applied in a plasma dissociation furnace tube system. Referring FIG. 4, FIG. 4 is a schematic diagram of a plasma dissociation furnace tube system 200 in accordance with an embodiment of the present disclosure. The plasma dissociation furnace tube system 200 may be a plasma-enhanced deposition system, such as a plasma-enhanced atomic layer deposition (PEALD) system. The plasma dissociation furnace tube system 200 may mainly include a furnace tube 300, the wafer boat device 100 as mentioned above, a gas extraction device 400, a power module 500, a process gas supply system 600, and a precursor gas supply system 700.

The furnace tube 300 has a reaction chamber 302. The furnace tube 300 is made of a material that can withstand the temperature of the plasma-enhanced deposition process. In some examples, the furnace tube 300 is a quartz furnace tube. The wafer boat device 100 is disposed in the reaction chamber 302 of the furnace tube 300, such that the wafers carried by the wafer boat device 100 can undergo a plasma-enhanced deposition process in the reaction chamber 302.

The gas extraction device 400 can be fluidly connected to the reaction chamber 302 through a pipeline, such that the gas extraction device 400 can perform a gas extraction operation on the reaction chamber 302. Specifically, the gas extraction device 400 may perform the gas extraction operation on the reaction chamber 302 from the feed region 150 to form a gas flow in the reaction chamber 302 toward the feed region 150, such that the plasma generated in the plasma region 130 can be driven to flow to the coating region 140.

The power module 500 is electrically connected to the first positive electrode plate 110a, the first positive electrode plate 110b, the first negative electrode plate 120, the second positive electrode plates 132, the second negative electrode plates 134, the fourth positive electrode plates 152, and the fourth negative electrode plates 154. Therefore, the power module 500 can supply power to the first positive electrode plate 110a, the first negative electrode plate 120, the feed region 150, and the plasma region 130. The power module 500 supplies power from the feed region 150, and current flows from the feed region 150 to the first positive electrode plate 110a, the first negative electrode plate 120, and the second positive electrode plates 132 and the second negative electrode plates 134 of the plasma region 130. In some examples, the power module 500 is a radio frequency power module, and a working frequency of the power module 500 is 40 kHz.

The process gas supply system 600 can be fluidly connected to the reaction chamber 302 of the furnace tube 300 by using a pipeline. The process gas supply system 600 may supply at least one process gas to the reaction chamber 302. In some examples, the process gas supply system 600 is adjacent to the plasma region 130, and the process gas supply system 600 may supply the process gas to the plasma region 130 in the reaction chamber 302 through the furnace tube 300. For example, the process gas may be redox gases, such as oxygen, nitrous oxide, and water. When the process gas is introduced into the plasma region 130, the process gas is dissociated due to the electric field in the plasma region 130 to generate plasma. The plasma generated from the process gas flows to the coating region 140 driven by the gas flow, and forms dangling bonds on the surfaces of the wafers carried by the coating region 140. The process gas supply system 600 may further include a rapid pneumatic valve and a flow meter (not shown) to control the supply of the process gas.

The precursor gas supply system 700 can be fluidly connected to the reaction chamber 302 of the furnace tube 300 through a pipeline. The precursor gas supply system 700 may supply at least one precursor gas to the reaction chamber 302. In some examples, the precursor gas supply system 700 may supply the precursor gas from a bottom of the wafer boat device 100 through the furnace tube 300. The precursor gas can bond with the dangling bonds on the surfaces of the wafers carried by the coating region 140 and adhere to the surfaces of the wafers to form coating films. For example, the precursor gas may be TMA, BDESA, DEZ, TTIP, TMG, TMI, TDMA-Hf, MeCpPtMe3, etc. The precursor gas supply system 700 may further include a rapid pneumatic valve and a flow meter (not shown) to control the supply of the precursor gas.

The plasma dissociation furnace tube system 200 may be a plasma-enhanced atomic layer deposition apparatus. For example, the plasma dissociation furnace tube system 200 may be used to deposit atomic layers, such as silicon oxide films, polycrystalline silicon films, zirconium oxide films, hafnium oxide films, silicon carbide films, titanium carbide films, tantalum nitride films, tantalum carbonitride films, copper films, aluminum films, zinc films, tantalum films, titanium films, tungsten films, tungsten nitride films, gallium nitride films, or any combination thereof.

According to the aforementioned embodiments, one advantage of the present disclosure is that the coating region of the wafer boat device is separated from the plasma region and the feed region by the first circuit breaking region and the second circuit breaking region respectively, such that the current entering the wafer boat device from the feed region does not flow through the electrode plates in the coating region. As a result, the plasma with high bombardment energy will not be generated between the wafers in the coating region. Therefore, the plasma bombardment on the films on the wafers carried by the coating region can be reduced, and the coverage and the density of the films are increased, thereby enhancing the quality of the films and the photoelectric conversion efficiency of the solar cells to achieve large-area batch plasma-enhanced deposition.

Another advantage of the present disclosure is that the reaction chamber is evacuated from the feed region by the gas extraction device to form a gas flow in the reaction chamber to drive the plasma generated in the plasma region to flow to the coating region to perform a plasma-enhanced coating operation. The plasma dissociates in the plasma region next to the coating region, such that compared with the traditional remote plasma system, the present disclosure can ensure the stability of the plasma dissociation gas which flows to the coating region, thereby enhancing coating efficiency and film quality. Furthermore, with the method of dissociating the plasma in the plasma region and then driving the plasma to the adjacent coating region, even if the wafer warps due to the gas flow and temperature, there will be no short circuit caused by plasma bombardment because no current flows through the wafer.

Although the present disclosure has been disclosed above with embodiments, it is not intended to limit the present disclosure. Any person having ordinary skill in the art can make various changes and modifications without departing from the spirit and scope of the present disclosure. Therefore, the protection scope of the present disclosure should be defined by the scope of the appended claims.

What is claimed is:

1. A wafer boat device, comprising:
a first positive electrode plate;
a first negative electrode plate opposite to the first positive electrode plate;
a plasma region disposed between the first positive electrode plate and the first negative electrode plate, wherein the plasma region comprises a plurality of second positive electrode plates and a plurality of second negative electrode plates;
a coating region disposed between the first positive electrode plate and the first negative electrode plate, and separated from the plasma region by a first circuit breaking region, wherein the coating region comprises a plurality of third positive electrode plates and a plurality of third negative electrode plates, and each of the third positive electrode plates and the third negative electrode plates is configured to carry a plurality of cells; and
a feed region disposed between the first positive electrode plate and the first negative electrode plate, and separated from the coating region by a second circuit breaking region, wherein the feed region comprises a plurality of fourth positive electrode plates and a plurality of fourth negative electrode plates, and the feed region is electrically connected to the plasma region,
wherein all the second positive electrode plates and the second negative electrode plates, the third positive electrode plates and the third negative electrode plates, and the fourth positive electrode plates and the fourth negative electrode plates are arranged at intervals from each other in a staggered manner with the first positive electrode plate and the first negative electrode plate.

2. The wafer boat device of claim 1, further comprising:
another first positive electrode plate disposed adjacent to the first negative electrode plate, such that the first negative electrode plate being between the another first positive electrode plate and the first positive electrode plate; or
another first negative electrode plate disposed adjacent to the first positive electrode plate, such that the first positive electrode plate being between the another first negative electrode plate and the first negative electrode plate.

3. The wafer boat device of claim 1, wherein the first circuit breaking region electrically isolates the coating region from the plasma region, and the second circuit breaking region electrically isolates the feed region from the coating region.

4. The wafer boat device of claim 1, wherein a length of each of the first circuit breaking region and the second circuit breaking region is ranging from 50 mm to 80 mm.

5. The wafer boat device of claim 1, wherein an electrical conductivity of the first positive electrode plate and an electrical conductivity of the first negative electrode plate are both greater than a plurality of electrical conductivities of the second positive electrode plates, the second negative electrode plates, the third positive electrode plates, the third positive electrode plates, the fourth positive electrode plates, and the fourth negative electrode plates.

6. The wafer boat device of claim 5, wherein a ratio of the electrical conductivity of the first positive electrode plate to each of the electrical conductivities of the second positive electrode plates, the third positive electrode plates, and the fourth positive electrode plates is ranging from 2.5:1 to 175:1, and a ratio of the electrical conductivity of the first negative electrode plate to each of the electrical conductivities of the second negative electrode plates, the third negative electrode plates, and the fourth negative electrode plates is ranging from 2.5:1 to 175:1.

7. The wafer boat device of claim 1, wherein each of the first positive electrode plate and the first negative electrode plate comprises:
a main body; and
a metal layer covering at least one side surface of the main body, wherein an electrical conductivity of the metal layer is greater than an electrical conductivity of the main body.

8. The wafer boat device of claim 7, wherein a material of the metal layer comprises copper paste or silver paste, and a material of the main body comprises graphite.

9. The wafer boat device of claim 7, wherein materials of the second positive electrode plates, the second negative electrode plates, the third positive electrode plates, the third negative electrode plates, the fourth positive electrode plates, and the fourth negative electrode plates comprise graphite.

10. A plasma dissociation furnace tube system, comprising:
a furnace tube having a reaction chamber;
a wafer boat device as claimed in claim 1 disposed in the reaction chamber;
a gas extraction device fluidly connected to the reaction chamber, wherein the gas extraction device is configured to perform a gas extraction operation on the reaction chamber from the feed region to drive a plasma generated in the plasma region to flow to the coating region;
a power module electrically connected to the first positive electrode plate, the second positive electrode plates, the fourth positive electrode plates, the first negative electrode plate, the second negative electrode plates, and the four negative electrode plates, and configured to supply a power to the first positive electrode plate, the first negative electrode plate, the feed region, and the plasma region;
a process gas supply system fluidly connected to the reaction chamber and configured to supply at least one process gas to the reaction chamber; and
a precursor gas supply system fluidly connected to the reaction chamber and configured to supply at least one precursor gas to the reaction chamber.

11. The plasma dissociation furnace tube system of claim 10, wherein the power module is a radio frequency power module, and a working frequency of the power module is 40 kHz.

12. The plasma dissociation furnace tube system of claim 10, wherein the process gas supply system is adjacent to the plasma region, and the process gas supply system is configured to supply the at least one process gas toward the plasma region.

13. The plasma dissociation furnace tube system of claim 10, wherein the precursor gas supply system is configured to supply the at least one precursor gas from a bottom of the wafer boat device.

14. The plasma dissociation furnace tube system of claim 10, wherein the wafer boat device further comprises:
another first positive electrode plate disposed adjacent to the first negative electrode plate, such that the first negative electrode plate being between the another first positive electrode plate and the first positive electrode plate; or
another first negative electrode plate disposed adjacent to the first positive electrode plate, such that the first positive electrode plate being between the another first negative electrode plate and the first negative electrode plate.

15. The plasma dissociation furnace tube system of claim 10, wherein the first circuit breaking region electrically isolates the coating region from the plasma region, and the second circuit breaking region electrically isolates the feed region from the coating region.
